(19) United States
(12) Patent Application Publication
(10) Pub. No.: US 2026/0092976 A1
(43) Pub. Date: Apr. 2, 2026

(54) SYSTEMS AND METHODS FOR DISPLAYING PREDICTIVE STATE OF CHARGE

(71) Applicant: Apple Inc., Cupertino, CA (US)

(72) Inventors: Rui Wang, Irvine, CA (US); Guangyu Liu, San Jose, CA (US); Wei He, San Jose, CA (US); Chiyun Xia, Tustin, CA (US); Jun Hou, San Jose, CA (US)

(21) Appl. No.: 19/300,207

(22) Filed: Aug. 14, 2025

Related U.S. Application Data
(60) Provisional application No. 63/700,203, filed on Sep. 27, 2024.

(51) Int. Cl. G01R 31/374; G01K 3/00; G01R 31/371; G01R 31/382; G01S 19/13

(52) U.S. Cl. CPC G01R 31/374; G01K 3/005; G01R 31/371; G01R 31/382; G01S 19/13

(57) ABSTRACT

User equipment (UE) may be configured to determine a predictive shutdown point associated with a battery of the UE. The predictive shutdown point may indicate a predicted percent of the total amount of charge of the battery at which the UE may initiate a sleep mode and/or a shutdown operation. The UE may determine the predictive shutdown point based on an ambient temperature associated with a predicted location of the UE. The UE may receive a predicted location of the UE, determine the ambient temperature is lower than a threshold temperature, and determine the predicted shutdown point based on the ambient temperature. Furthermore, the UE may be configured to display the predictive shutdown point relative to a current state of charge associated with the battery of the UE to notify a user of potential initiation of a sleep mode and/or a shutdown operation associated with the UE.

### CROSS-REFERENCE TO RELATED APPLICATION

This application claims priority to U.S. Provisional Application No. 63/700,203, filed Sep. 27, 2024, entitled “Systems and Methods for Displaying Predictive State of Charge,” the disclosure of which is incorporated by reference in its entirety for all purposes.

### BACKGROUND

The present disclosure relates generally to a power source (e.g., a battery) of user equipment (UE), and more specifically to displaying information relating to the power source.

User equipment (UE), such as a mobile device, may operate and/or be powered via a battery. The UE may display an indication of an amount of available charge of the battery to power operations of the UE. For instance, the UE may display an indication of a shutdown point associated with the battery. The shutdown point may indicate a point at which the battery would not have a sufficient amount of charge to continue normal operations of the UE.

An amount of available power of the battery (e.g., until initiation of a sleep mode and/or shutdown operation) may be affected by ambient conditions associated with the UE. For example, in some cases, chemical characteristics of the battery may be temperature dependent. For example, a decrease in temperature of the battery to a temperature below and/or at the lower range of a threshold operational temperature range may cause a decrease in capacity of the battery, cause a decrease in speed of chemical reactions of the battery, and/or increase a resistance associated with the battery. As such, the battery may carry less charge and less amount of power as compared to the battery at higher temperatures (e.g., temperatures within the operational temperature range). As a temperature associated with the battery decreases, the shutdown point associated with the battery may increase (e.g., due to the amount of available charge decreasing), which in turn decreases the current state of charge of the battery (e.g., independent of use of the battery to power operations of the UE). As such, the UE may initiate a shutdown operation before a user is expecting due to the temperature decrease.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, one or more tangible, non-transitory, computer-readable media comprising instructions, that when executed by processing circuitry of a user equipment, cause the processing circuitry to receive a state of charge of a power source of the user equipment, receive an ambient temperature of a location associated with the user equipment, and provide an indication of a predicted shutdown point based on the ambient temperature being less than or equal to a threshold ambient temperature.

In another embodiment, an electronic device includes a receiver and processing circuitry coupled to the receiver. The processing circuitry is configured to receive a state of charge of a power source of the electronic device, receive an ambient temperature of a location associated with the electronic device, determine a predicted shutdown point associated with the state of charge based on the ambient temperature, and provide an indication of the predicted shutdown point based on the ambient temperature being less than a threshold ambient temperature.

In yet another embodiment, a method performed by an electronic device, the method including receiving, via processing circuitry of the electronic device, a state of charge of a power source of the electronic device. The method further includes receiving, via the processing circuitry, a first indication that a predictive shutdown operation associated with the electronic device is enabled, receiving, at the processing circuitry, an ambient temperature of a location associated with the electronic device based on the predictive shutdown operation being enabled, and displaying, via a display of the electronic device, a second indication of the predicted shutdown point and the state of charge based on the ambient temperature being less than or equal to the threshold ambient temperature. The method further includes displaying, via the display, a third indication of the state of charge based on the ambient temperature being greater than the threshold ambient temperature.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings described below in which like numerals refer to like parts.

FIG. 1 is a block diagram of user equipment, according to embodiments of the present disclosure;

FIG. 2 is a functional diagram of the user equipment of FIG. 1, according to embodiments of the present disclosure;

FIG. 3 is a flowchart of a method for user equipment of FIG. 1 to display an indication of a predicted shutdown point, according to embodiments of the present disclosure; and

FIG. 4 is a schematic diagram of example indications of a state of charge relative to a shutdown point that are displayed by the user equipment of FIG. 1, according to embodiments of the present disclosure.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1 % of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on. Additionally, the term “set” may include one or more. That is, a set may include a unitary set of one member, but the set may also include a set of multiple members.

This disclosure is directed to determining a predictive shutdown point (e.g., predictive shutdown threshold) associated with a battery of user equipment (UE), and displaying an indication of the predictive shutdown point relative to a current state of charge associated with the battery of the UE. The UE may include an electronic device, such as a mobile device, a cell phone, a tablet, a laptop, a smart watch, and/or an electric vehicle. In addition, the UE may include a power source, such as a battery, that provides or supplies charge (e.g., power, energy, electricity, voltage) for operations of the UE. The UE may determine (e.g., track) an amount of available charge of the battery to power operations of the UE. For instance, the UE may determine a shutdown point (e.g., a shutdown threshold) associated with the battery. The shutdown point may include a percent of the total amount of charge of the battery (e.g., 0%, 5%, 2%) at which the battery would not provide a sufficient amount of charge to continue normal operations of the UE. In addition, the UE may determine the current state of charge of the battery. The current state of charge of the battery may include an available amount of charge of the battery to power the operations of the UE. The current state of charge may include a percentage of a total amount of charge of the battery (e.g., 10%, 25%, 55%) that is available to power operations of the UE. The current state of charge may indicate an amount of charge available to power operations of the UE prior to reaching the shutdown point. In some embodiments, the UE may initiate a sleep mode and/or a shutdown operation in response to the current state of charge being equal to and/or within a threshold amount of the shutdown point.

For improved user experience, the UE may display, via a display associated with the UE, an indication of the current state of charge and/or the shutdown point. In some embodiments, the UE may display an indication of the current state of charge in relation to the indication of the shutdown point. Displaying the indication of the current state of charge in relation to the indication of the shutdown point may notify a user of the UE as to an amount of remaining charge of the battery prior to initiation of a sleep mode or shutdown operations. Displaying the indication of the current state of charge in relation to the indication of the shutdown point may additionally allow users to more accurately determine when to recharge the battery for further use of the UE and/or in effort to avoid unexpected initiation of sleep mode or shutdown operations. For example, the UE may present the indication of the current state of charge in relation to the indication of the shutdown point as a visual indication, such as a symbol, an icon, and/or text on a graphical user interface (GUI) of the UE, an audio indication, via output device (e.g., speakers) associated with the UE, or both to indicate to a user an amount of charge remaining associated with the battery.

However, in some embodiments, an amount of available charge of the battery (e.g., until initiation of a sleep mode and/or shutdown operation) may be affected (e.g., adjusted, changed, decreased, increased) by ambient conditions associated with the UE. For example, the amount of available charge (e.g., power, capacity, resistance) of the battery may be affected by exposure to an ambient temperature of an environment in which the UE is located (e.g., is exposed to). In particular, a temperature of the battery may correspond to the ambient temperature. In addition, in some embodiments, chemical characteristics of the battery may be temperature dependent. As such, efficient operation of the battery (e.g., amount of available charge, discharge performance, capacity) may depend on a temperature of the battery. Furthermore, efficient operation of the battery may be within an operational temperature range. As an example, the battery may include a lithium ion battery that may include an operational temperature range of −10 degrees Celsius (° C.) to 55° C.

Operation of the UE, via the battery, at temperatures (e.g., ambient temperatures, battery temperatures) below and/or within a lower temperature range (e.g., −10° C., −20° C., −25° C., −30° C., 10° C. to −10° C.) than that of an operational temperature range of the battery may affect an amount of available charge of the battery. In particular, a decrease in a temperature of the battery (e.g., to a temperature below and/or at the lower range of the operational temperature range) may affect the shutdown point, and thus the current state of charge in relation to the shutdown point. For example, a decrease in the temperature of the battery may cause a decrease in capacity of the battery, cause a decrease in speed of chemical reactions of the battery, and/or increase a resistance associated with the battery. As such, a decrease in the temperature of the battery may cause the battery to have an amount of available charge that is less than an amount of available charge at higher temperatures (e.g., temperatures within the operational temperature range). In particular, as the temperature of the battery decreases, the shutdown point associated with the battery may increase (e.g., due to the amount of available charge decreasing), which in turn decreases the current state of charge of the battery in relation to the shutdown point (e.g., independent of use of the battery to power operations of the UE). In some instances, at lower ambient temperatures, the temperature of the battery may decrease and the UE may unexpectantly initiate a sleep mode or a shutdown operation in response to the decreasing temperature of the battery.

Conditions in which the battery may experience lower ambient temperatures and thus a decrease in the temperature associated with the battery may include locations (e.g., geographical locations) with cold weather climates, cold environments, higher altitude environments, greater diving depths, and the like. As an example, a UE may travel (e.g., via a user) from an indoor location with an ambient temperature of 24° C. to an outdoor location with an ambient temperature of −10° C. When the UE is at the indoor location, the current state of charge may be 25% in relation to the shutdown point, which may be at 0% of a total amount of charge of the battery. However, when the user travels with the UE from the indoor environment to the outdoor environment, the lower ambient temperature may cause the temperature of the battery to decrease (e.g., from approximately 24° C. to approximately −10° C.). To this end, the shutdown point may change (e.g., increase, due to a decrease in temperature of the battery) to 20% of total amount of charge of the battery, and thus the current state of charge may change (e.g., decrease, due to a decrease in temperature of the battery) from 25% to 5% in relation to (e.g., from) the shutdown point of 20%, independent of use of the battery to power operations of the UE. As such, the UE may initiate a shutdown operation in response to the current state of charge being within a threshold amount from the shutdown point. Unfortunately, the user may not have expected the shutdown operation to occur due to the display of the current state of charge indicating 25% in the indoor environment, and thus the shutdown operation of the UE (e.g., due to exposure to lower ambient temperatures) may negatively impact user experience associated with the UE.

Therefore, embodiments herein determine a predictive shutdown point (e.g., predictive shutdown threshold) associated with a battery of user equipment (UE). The predictive shutdown point may indicate a future or predicted percent of the total amount of charge of the battery (e.g., 5%, 10%, 12%, 20%) at which the battery may not provide a sufficient amount of charge to continue normal operations of the UE. In addition, in some embodiments, the predictive shutdown point may indicate a predicted point at which the UE may initiate a sleep mode and/or a shutdown operation. The UE may determine the predictive shutdown point based on a predicted temperature associated with the UE (e.g., with the battery). For example, the UE may receive an indication of future exposure to an ambient temperature (e.g., a predicted ambient temperature, a future ambient temperature) that is lower than a threshold temperature, and determine (e.g., calculate) the predicted shutdown point based on the ambient temperature.

Furthermore, embodiments herein provide for displaying an indication of the predictive shutdown point relative to a current state of charge associated with the battery of the UE. Displaying the indication of the predictive shutdown point may efficiently and effectively notify (e.g., warn, alert) a user of potential initiation of a sleep mode and/or a shutdown operation associated with the UE. For example, display of the predictive shutdown point may indicate a potential sleep mode and/or a potential shutdown operation shutdown operation when the current state of charge of the battery is equal to, less than, or within a threshold amount of the predictive shutdown point. As such, the user may choose to recharge the battery (e.g., prior to exposure to the predicted ambient temperature) to avoid any future initiations of a sleep mode and/or a shutdown operation. As such, the present embodiments provide for improved battery tracking performance by the UE, and thus improved user experience.

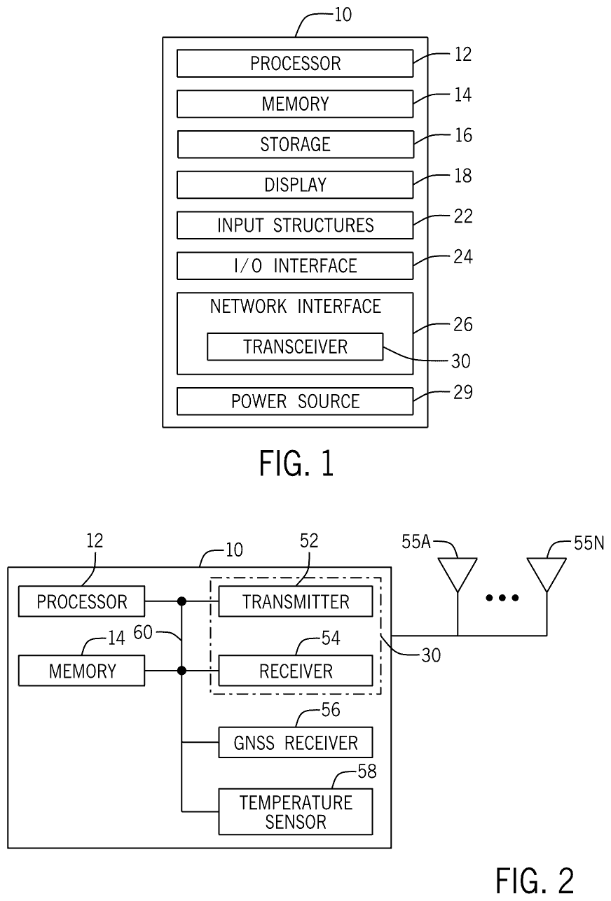

With the foregoing in mind, FIG. 1 is a block diagram of user equipment (UE) 10, according to embodiments of the present disclosure. The UE 10 may include, among other things, one or more processors 12 (collectively referred to herein as a single processor for convenience, which may be implemented in any suitable form of processing circuitry), memory 14, nonvolatile storage 16, a display 18, input structures 22, an input/output (I/O) interface 24, a network interface 26, and a power source 29 (e.g., battery). The various functional blocks shown in FIG. 1 may include hardware elements (including circuitry), software elements (including machine-executable instructions) or a combination of both hardware and software elements (which may be referred to as logic). The processor 12, memory 14, the nonvolatile storage 16, the display 18, the input structures 22, the input/output (I/O) interface 24, the network interface 26, and/or the power source 29 may each be communicatively coupled directly or indirectly (e.g., through or via another component, a communication bus, a network) to one another to transmit and/or receive signals between one another. It should be noted that FIG. 1 is merely one example of a particular implementation and is intended to illustrate the types of components that may be present in the UE 10.

By way of example, the UE 10 may include any suitable computing device, including a desktop or notebook computer, a portable electronic or handheld electronic device such as a wireless electronic device or smartphone, a tablet, a wearable electronic device, and other similar devices. In additional or alternative embodiments, the UE 10 may include an access point, such as a base station, a router (e.g., a wireless or Wi-Fi router), a hub, a switch, and so on. It should be noted that the processor 12 and other related items in FIG. 1 may be embodied wholly or in part as software, hardware, or both. Furthermore, the processor 12 and other related items in FIG. 1 may be a single contained processing module or may be incorporated wholly or partially within any of the other elements within the UE 10. The processor 12 may be implemented with any combination of general-purpose microprocessors, microcontrollers, digital signal processors (DSPs), field programmable gate array (FPGAs), programmable logic devices (PLDs), controllers, state machines, gated logic, discrete hardware components, dedicated hardware finite state machines, or any other suitable entities that may perform calculations or other manipulations of information. The processors 12 may include one or more application processors, one or more baseband processors, or both, and perform the various functions described herein.

In the UE 10 of FIG. 1, the processor 12 may be operably coupled with a memory 14 and a nonvolatile storage 16 to perform various algorithms. Such programs or instructions executed by the processor 12 may be stored in any suitable article of manufacture that includes one or more tangible, computer-readable media. The tangible, computer-readable media may include the memory 14 and/or the nonvolatile storage 16, individually or collectively, to store the instructions or routines. The memory 14 and the nonvolatile storage 16 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by the processor 12 to enable the UE 10 to provide various functionalities.

In certain embodiments, the display 18 may facilitate users to view images generated on the UE 10. In some embodiments, the display 18 may include a touch screen, which may facilitate user interaction with a user interface of the UE 10. Furthermore, it should be appreciated that, in some embodiments, the display 18 may include one or more liquid crystal displays (LCDs), light-emitting diode (LED) displays, organic light-emitting diode (OLED) displays, active-matrix organic light-emitting diode (AMOLED) displays, or some combination of these and/or other display technologies.

The input structures 22 of the UE 10 may enable a user to interact with the UE 10 (e.g., pressing a button to increase or decrease a volume level). The I/O interface 24 may enable UE 10 to interface with various other UE, as may the network interface 26. In some embodiments, the I/O interface 24 may include an I/O port for a hardwired connection for charging and/or content manipulation using a standard connector and protocol, such as the Lightning connector, a universal serial bus (USB), or other similar connector and protocol. The network interface 26 may include, for example, one or more interfaces for a personal area network (PAN), such as an ultra-wideband (UWB) or a Bluetooth network, a radio access network (RAN), a local area network (LAN) or wireless local area network (WLAN), such as a network employing one of the IEEE 802.11x family of protocols (e.g., Wi-Fi), and/or a wide area network (WAN), such as any standards related to the Third Generation Partnership Project (3GPP), including, for example, a 3^{rd} generation (3G) cellular network, universal mobile telecommunication system (UMTS), 4^{th} generation (4G) cellular network, Long Term Evolution (LTE) cellular network, Long Term Evolution License Assisted Access (LTE-LAA) cellular network, 5^{th} generation (5G) cellular network, and/or New Radio (NR) cellular network, a 6^{th} generation (6G) or greater than 6G cellular network, a satellite network, a non-terrestrial network, and so on. In particular, the network interface 26 may include, for example, one or more interfaces for using a cellular communication standard of the 5G specifications that include the millimeter wave (mmWave) frequency range (e.g., 24.25-300 gigahertz (GHz)) that defines and/or enables frequency ranges used for wireless communication. The network interface 26 of the UE 10 may allow communication over the aforementioned networks (e.g., 5G, Wi-Fi, LTE-LAA, and so forth).

The network interface 26 may also include one or more interfaces for, for example, broadband fixed wireless access networks (e.g., WIMAX), mobile broadband Wireless networks (mobile WIMAX), asynchronous digital subscriber lines (e.g., ADSL, VDSL), digital video broadcasting-terrestrial (DVB-T) network and its extension DVB Handheld (DVB-H) network, ultra-wideband (UWB) network, alternating current (AC) power lines, and so forth.

As illustrated, the network interface 26 may include a transceiver 30. In some embodiments, all or portions of the transceiver 30 may be disposed within the processor 12. The transceiver 30 may support transmission and receipt of various wireless signals via one or more antennas, and thus may include a transmitter and a receiver. The power source 29 of the UE 10 may include any suitable source of power, such as a rechargeable lithium polymer (Li-poly) battery and/or an alternating current (AC) power converter. In some embodiments, the power source 29 of the UE 10 may include a rechargeable battery, such as a lead-acid battery, a nickel-cadmium (NiCd) battery, and/or a nickel-metal hydride (NiMH) battery.

FIG. 2 is a functional diagram of the UE 10 of FIG. 1, according to embodiments of the present disclosure. As illustrated, the processor 12, the memory 14, the transceiver 30, a transmitter 52, a receiver 54, and/or antennas 55 (illustrated as 55A-55N, collectively referred to as an antenna 55) may be communicatively coupled directly or indirectly (e.g., through or via another component, a communication bus, a network) to one another to transmit and/or receive signals between one another.

The UE 10 may include the transmitter 52 and/or the receiver 54 that respectively enable transmission and reception of signals between the UE 10 and an external device via, for example, a network (e.g., including base stations or access points) or a direct connection. As illustrated, the transmitter 52 and the receiver 54 may be combined into the transceiver 30. The UE 10 may also have one or more antennas 55A-55N electrically coupled to the transceiver 30. The antennas 55A-55N may be configured in an omnidirectional or directional configuration, in a single-beam, dual-beam, or multi-beam arrangement, and so on. Each antenna 55 may be associated with one or more beams and various configurations. In some embodiments, multiple antennas of the antennas 55A-55N of an antenna group or module may be communicatively coupled to a respective transceiver 30 and each emit radio frequency signals that may constructively and/or destructively combine to form a beam. The UE 10 may include multiple transmitters, multiple receivers, multiple transceivers, and/or multiple antennas as suitable for various communication standards. In some embodiments, the transmitter 52 and the receiver 54 may transmit and receive information via other wired or wireline systems or means.

The UE 10 may include the GNSS receiver 56 that may enable the UE 10 to receive GNSS signals from a GNSS network that includes one or more GNSS satellites or GNSS ground stations. The GNSS signals may include timing information, such as Global Positioning System (GPS) date, satellite clock correction information, satellite status, and so on. The UE 10 may compare the timing information in the GNSS signals with internal clock signals (e.g., from an oscillator). The UE 10 may adjust the internal clock signals based on the timing information. The GNSS signals may also include a GNSS satellite's observation data, broadcast orbit information of tracked GNSS satellites, and supporting data, such as meteorological parameters, collected from co-located instruments of a GNSS satellite. For example, the GNSS signals may be received from a Global Positioning System (GPS) network, a Global Navigation Satellite System (GLONASS) network, a BeiDou Navigation Satellite System (BDS), a Galileo navigation satellite network, a Quasi-Zenith Satellite System (QZSS or Michibiki) and so on. The GNSS receiver 56 may process the GNSS signals to determine a global position of the UE 10.

The UE 10 may include a temperature sensor 58 to measure temperature of certain components (e.g., the power source 29, internal components) of the UE 10. In some cases, changes in temperature may alter or affect performance certain components of the UE 10. For example, temperature may affect or impact performance of the power source 29, such as a battery, by affecting chemical processes associated with the battery. The UE 10 may determine, track, and/or monitor temperatures of the UE 10 (e.g., the power source 29) based on sensor data received from the temperature sensor 58.

As illustrated, the various components of the UE 10 may be coupled together by a bus system 60. The bus system 60 may include a data bus, for example, as well as a power bus, a control signal bus, and a status signal bus, in addition to the data bus. The components of the UE 10 may be coupled together or accept or provide inputs to each other using some other mechanism.

The UE 10 may be exposed to varying ambient conditions. For example, the UE 10 may be located (e.g., positioned) in one or more environments. As such, the UE 10 may be exposed to the respective ambient conditions associated with the one or more environments. In other words, the ambient conditions experienced by the UE 10 may vary based on a location (e.g., geographical location) of the UE 10. For example, the one or more environments may include an indoor environment (e.g., climate controlled environment, shelter, building), an outdoor environment, an underwater environment (e.g., swimming, diving, scuba diving), and/or a higher altitude environment (e.g., hiking, mountain climbing, sky diving, parachuting). Each of the environments may include respective ambient conditions, such as an ambient temperature, an ambient pressure, an ambient humidity, or a combination thereof associated with the environment. The respective ambient conditions may differ between the environments. For example, an ambient temperature associated with the indoor environment may be different (e.g., higher, lower) than the ambient temperature associated with the outdoor environment. It should be appreciated that in some embodiments, the respective ambient conditions between different environments may be approximately the same. In addition, it should be understood that, although the indoor environment (e.g., climate controlled environment, shelter, building), the outdoor environment, the underwater environment (e.g., swimming, diving, scuba diving), and the higher altitude environment are discussed herein, the UE 10 may be located in additional environments with additional ambient conditions (e.g., underground cave, industrial freezer, ice skating, cryotherapy, ice bath, cold weather conditions, night-time conditions).

Furthermore, in some embodiments, the UE 10 may be associated with a user. In some embodiments, the UE 10 may be worn or carried by the user. For example, the UE 10 may include a mobile device (e.g., user device), such as a cell phone, smartwatch, tablet, earbud, laptop, and the like. In some embodiments, the UE 10 may be operated by the user. For example, the UE 10 may include an electric vehicle or hybrid electric vehicle. The user may be located in and/or may travel to or between the one or more environments (e.g., via the user). It should be appreciated that the UE 10 may be transported to and/or between the various environments by other methods, such as a vehicle, via a robot, a drone, and the like. In some embodiments, the UE 10 may be part of, coupled to, attached to, or affixed to an autonomous vehicle and travel to and/or between the one or more environments (e.g., with the user present, without the user present) autonomously. The UE 10 may be exposed to the respective ambient conditions, such as an ambient temperature, an ambient pressure, an ambient humidity, or a combination thereof associated with the one or more environments. In particular, the UE 10 may be exposed to an ambient temperature associated with a respective environment at which the UE 10 is located.

In addition, the ambient temperature of the environment may affect or influence a temperature of the UE 10 (e.g., internal temperature of the UE 10, a temperature of the power source or battery). In particular, in some embodiments, the temperature of the UE 10 may correspond (e.g., correlate, match, be approximately equal) to the ambient temperature of the respective environment (e.g., location) at which the UE 10 is located. As such, the temperature of the UE 10 may differ (e.g., change, adjust) based on the location of the UE 10. In some embodiments, the temperature of the UE 10 may change (e.g., adjust) based on the ambient temperature. In particular, the temperature of the UE 10 may change in response to a temperature change (e.g., increase in temperature, decrease in temperature) of the ambient temperature. For example, the temperature of the UE 10 may decrease in response to a decrease in the ambient temperature associated with an environment at which the UE 10 is located.

As discussed herein, performance of certain operations of the UE 10 may be temperature dependent. For example, efficient operation of the battery of the UE 10 (e.g., amount of available charge, discharge performance, capacity) may depend on a temperature of the battery. The temperature of the UE 10 may correspond to the temperature of the battery. In particular, an amount of available charge (e.g., power, capacity, resistance) of the battery may be affected by an ambient temperature of the environment in which the UE 10 is located (e.g., is exposed to). To this end, efficient or normal operation of the battery (e.g., where operational parameters of the battery fall within threshold performance levels) may occur within an operational temperature range. As an example, the battery may include a lithium ion battery that may have an operational temperature range of −10 degrees Celsius (° C.) to 55° C. It should be appreciated that the battery may include a lead-acid battery, a nickel-cadmium (NiCd) battery, a nickel-metal hydride (NiMH) battery, or a lithium-ion battery. In particular, the battery may include a rechargeable battery.

Operation of the UE 10, and thus the battery, at ambient temperatures below and/or within a lower temperature range (e.g., −10° C., −20° C., −25° C., −30° C., 10° C. to −10° C.) than that of the operational temperature range of the battery may decrease the amount of available charge of the battery. For example, a decrease in the temperature of the battery may cause a decrease in capacity of the battery, cause a decrease in speed of chemical reactions of the battery, and/or increase a resistance associated with the battery. As such, a decrease in the temperature of the battery may cause the battery to have an amount of available charge that is less than an amount of available charge at a higher temperature (e.g., temperature within the optimal operation temperature range). In some instances, the UE 10 may be located in environments with lower ambient temperatures and thus, the temperature of the battery may decrease. The UE 10 may initiate a sleep mode or a shutdown operation in response to the decreasing temperature of the battery.

Accordingly, the UE 10 may determine a predictive shutdown point. In particular, the UE 10 may determine the predictive shutdown point based on a predicted temperature associated with the UE 10 (e.g., with the battery). The UE 10 may receive an indication of a predicted ambient temperature (e.g., predicted exposure to an ambient temperature) and determine the predicted shutdown point based on the predicted ambient temperature. In some embodiments, the indication of the predicted ambient temperature may be based on a predicted location (e.g., potential location, future location) of the UE 10. That is, the UE 10 may receive an indication of the predicted location of the UE 10 and determine the predicted ambient temperature associated with the predicted location. In particular, the UE 10 may receive location information indicative of a location of the UE 10 (e.g., a current location, the predicted location). The UE 10 may receive location information via the global navigation satellite system receiver 56 of the UE from a global navigation satellite system.

For example, the UE 10 may receive an indication that the UE 10 will potentially be located at the outdoor environment. The UE 10 may determine the predicted shutdown point based on an ambient temperature associated with the outdoor environment. In particular, in some embodiments, the UE 10 may determine that the predicted ambient temperature associated with the outdoor environment is lower than a threshold ambient temperature, and determine (e.g., calculate) the predicted shutdown point based on the predicted ambient temperature. In addition, the UE 10 may display an indication of the predicted shutdown point via a display associated with the UE 10. Display of the indication of the predicted shutdown point may notify the user as to a potential increase in the shutdown point of the UE 10 and/or a potential decrease in a current state of charge of the UE 10 should the UE 10 be located in the predicted location (e.g., the user travel with the UE 10 to the predicted location at a future time). The user may decide, based on the indication of the predicted shutdown point, to recharge the battery of the UE 10 prior to traveling to the predicted location to avoid unexpected sleep mode and/or a shutdown operation associated with the UE 10. Thus, the present embodiments may provide for more efficient and improved tracking of available charge of the battery, and may provide for improved user experience.

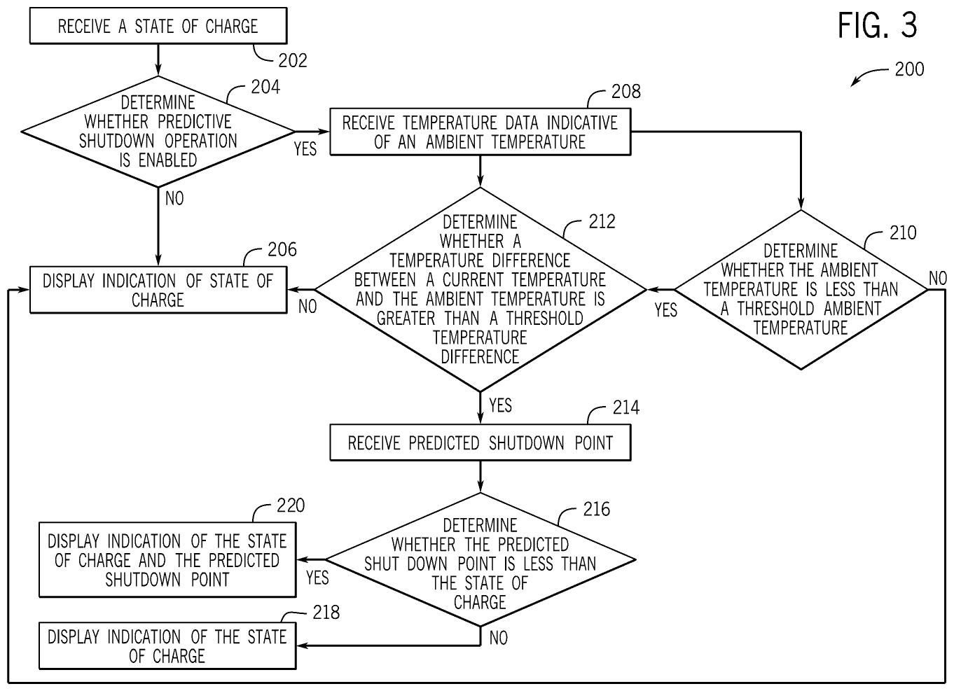

With the foregoing in mind, FIG. 3 is a flowchart of a method 200 for a UE 10 to display an indication of a predicted shutdown point, according to embodiments of the present disclosure. Any suitable device (e.g., a controller) that may control components of the UE 10, such as the processor 12, may perform the method 200. In some embodiments, the method 200 may be implemented by executing instructions stored in a tangible, non-transitory, computer-readable medium, such as the memory 14 or storage 16, using the processor 12. For example, the method 200 may be performed at least in part by one or more software components, such as an operating system of the UE 10, one or more software applications of the UE 10, and the like. While the method 200 is described using steps in a specific sequence, it should be understood that the present disclosure contemplates that the described steps may be performed in different sequences than the sequence illustrated, and certain described steps may be skipped or not performed altogether.

In some embodiments, the UE 10 may use machine learning and/or artificial intelligence to perform any of the steps or processes of method 200. As used herein, machine learning may refer to algorithms and statistical models that computer systems use to perform a specific task with or without using explicit instructions. For example, a machine learning process may generate a mathematical model based on a sample of clean data, known as “training data,” in order to make predictions or decisions without being explicitly programmed to perform the task.

In process block 202, the UE 10 may receive a state of charge (e.g., current state of charge) associated with a battery of the UE 10. The state of charge may include a ratio of remaining available charge of the battery to a maximum or total potential charge of the battery. In some embodiments, the state of charge may be expressed as a percentage of available charge of the battery with respect to a total charge of the battery. The UE 10 may determine (e.g., measure, calculate) the state of charge of the battery based on a variety of methods. For example, the UE 10 may utilize a voltage-based method in which the UE 10 may receive a cell voltage associated with the battery and estimate the state of charge based on the cell voltage. In some embodiments, the UE 10 may use a current-based method or Coulomb counting method in which the UE 10 may measure the current flowing into and out of the battery, and determine the state of charge based on these measurements. In some embodiments, the UE 10 may use an internal impedance method in which the UE 10 may receive a battery cell impedance associated with the battery and determine the state of charge based on the battery cell impedance. In some embodiments, the UE 10 may use a direct method in which the UE 10 may measure a rate of discharge of the battery and determine the state of charge based on the rate of discharge. In some embodiments, the UE 10 may use a specific gravity method in which the UE 10 may receive a specific gravity associated with the battery (e.g., via a suction hydrometer) and determine the state of charge based on the specific gravity. Additionally or alternatively, the UE 10 may receive a range (e.g., manufacturer's range) for voltage, current, and/or energy ratings associated with the battery and determine the state of charge based on a combination of any one of the aforementioned methods and one or more of the ranges.

At process block 204, the UE 10 may determine whether a predicted shutdown operation associated with the UE 10 is enabled. The predicted shutdown operation may include an operation, performed by the UE 10, that determines a predicted shutdown point based on a location (e.g., predicted location) of the UE 10. In addition, the UE 10 may include permissions associated with the predicted shutdown operation. For example, the permissions may determine whether the UE 10 determines the predicted shutdown point and/or whether the UE 10 displays an indication of the predicted shutdown point. In some embodiments, a user may enable or disable the predicted shut down operation. For example, the predicted shutdown operation may be enabled or disabled via user input (e.g., in a setting menu, selected via a graphical user interface (GUI) of the UE 10, voice command, actuated via a mechanical switch) by a user. As such, the UE 10 may check the permissions associated with the predicted shutdown operation to determine if the predicted shutdown operation is enabled or disabled.

If the UE 10 determines that the predicted shutdown operation is disabled, at process block 206, the UE 10 may display an indication of the state of charge of the battery. For example, the UE 10 may include a graphical user interface (GUI). In addition, the UE 10 may present the state of charge as a visual indication, such as a symbol, an icon, and/or text via the GUI. Additionally or alternatively, in some embodiments, the UE 10 may present the state of charge as an audio indication, via speakers associated with the UE 10. The indication of the state of charge may visually or audibly indicate an amount of remaining charge of the battery associated with the UE 10. For example, the indication may include image data indicative of an image, such as a shape (e.g., rectangle, circle, square, etc.), and the amount of remaining charge associated with the battery may be represented as a first portion of the shape that is “filled” or that is distinguished from a second portion of the shape that is associated with an amount of the battery that does not include an available amount of charge (e.g., empty of charge). In some embodiments, the first portion of the indication associated with the amount of remaining charge of the battery may include a first color that is different from a second color of the second portion of the shape associated with the amount of the battery that does not include an available amount of charge.

As an example, the indication may include an image of a rectangular shape. The rectangular shape may include an outline enclosing an interior space of the rectangle. When the state of charge of the battery is at 100%, the interior space of the rectangular shape may be completely filled with a first portion of a first color (e.g., grey, green, blue) to visually indicate the amount of remaining charge of the battery. When the state of charge of the battery is at 50%, the interior space of the rectangular shape may be half-way filled with the first portion to visually indicate the amount of the remaining charge of the battery. In other words, the first portion of the rectangular shape may include an area that is half of an area associated with the rectangular shape. The second portion of the rectangular shape may “fill” a portion of the interior space of the rectangular shape that is half of the area associated with the rectangular shape. In addition, the second portion may visually indicate the amount of battery that does not include an amount of available charge. Additionally, the second portion may include the second color (e.g., black, background color associated with the GUI of the UE 10) that is different from the first color.

In some embodiments, the UE 10 may additionally display an indication of a shutdown point associated with the UE 10. As discussed herein, the shutdown point may include a point at which the battery would not have sufficient amount of charge to continue normal operations of the UE 10 (e.g., operations available to the user and/or are able to be performed when the battery is fully charged). In addition, the shutdown point may include a ratio of remaining available charge of the battery to a maximum or total potential charge of the battery represented as a percentage of the total amount of charge of the battery (e.g., 0%, 5%) at which the battery would not have sufficient amount of charge to continue normal operations of the UE 10. In addition, the UE 10 may present the shutdown point as a visual indication, such as a symbol, an icon, and/or text via the GUI. Additionally or alternatively, in some embodiments, the UE 10 may present the shutdown point as an audio indication, via speakers associated with the UE 10. The indication of the shutdown point may visually or audibly indicate a point at which the UE 10 may initiate a sleep mode or a shutdown operation based on an amount of charge of the battery being less than a threshold amount of charge sufficient for normal operations of the UE 10. In addition, the indication of the shutdown point may be displayed in relation to the indication of the state of charge. For example, the indication of the state of charge may include a shape (e.g., rectangle, circle, square, etc.), and the indication of the shutdown point may visually indicate a point along the shape. In particular, the indication of the state of charge in relation to the shutdown point may indicate an amount of available charge of the battery from the shutdown point associated with the battery. In some embodiments, when the indication of the state of charge is visually equal to or within a threshold amount of the point along the shape (e.g., indication of the shutdown point), the indication of the state of charge in relation to the shutdown point may indicate that the UE 10 may initiate the sleep mode or shutdown operation.

Continuing with the above example, the amount of remaining charge associated with the battery may be represented as the first portion of the shape that is “filled” and/or that is distinguished from a second portion of the shape that is associated with an amount of the battery that does not include an available amount of charge (e.g., empty of charge). In addition, the shutdown point may be represented as an “end” of the rectangle, or as the battery discharges (e.g., the amount of remaining charge or the state of charge of the battery decreases), the first portion of the shape that is “filled” may decrease in size toward the “end” of the rectangle.

If the UE 10 determines that the predicted shutdown operation is enabled, at process block 208, the UE 10 may receive temperature data indicative of an ambient temperature associated with the UE 10. In some embodiments, the UE 10 may receive temperature data associated with an ambient temperature of a predicted location of the UE 10. In particular, the UE 10 may receive an indication of the predicted location of the UE 10. The predicted location may include a potential location (e.g., future location) of the UE 10. As an example, the UE 10 may receive an indication of travel or a route from a current location of the UE 10 to a destination or potential future location. The UE 10 may determine the predicted location based on the indication of travel or route. In particular, a user associated with the UE 10 may set a route of travel and/or a destination using a navigational application of the UE 10. In some embodiments, the UE 10 may receive the indication of the predicted location based on a calendar entry of a calendar application associated with the UE 10, a scheduled event of a calendar application associated with the UE 10, a reservation or booking of a calendar application or a virtual wallet application associated with the UE 10, a purchase of a virtual wallet application associated with the UE 10 (e.g., purchase item for pickup, grocery order), a ticket (e.g., concert ticket, plane ticket) of a virtual wallet application associated with the UE 10, an exercise route or program of an exercise or running application associated with the UE 10, a target diving depth of a diving application associated with the UE 10, or a hiking route of a navigation, hiking, or trail mapping application associated with the UE 10. Additionally or alternatively, the UE 10 may receive the indication of the predicted location based on a message (e.g., digital data or audio data) of a messaging application associated with the UE 10, such as a body or text of an email or text message, a voicemail, audio message, and/or phone call (e.g., live phone call).

The UE 10 may receive the temperature data based on the indication of the predicted location of the UE 10. In some embodiments, the UE 10 may receive the temperature data from applications associated with the UE 10, such as weather applications. In some embodiments, the UE 10 may receive the temperature data from the Internet. The UE 10 may query a database (e.g., external database, memory) that stores temperatures corresponding to respective predicted locations. The UE 10 may receive the temperature data from the database based on the predicted location. In some embodiments, the temperature data may be stored in look up tables and be associated with the respective predicted location. In some embodiments, the UE 10 may use machine learning and/or artificial intelligence to determine the ambient temperature based on the indication of the predicted location of the UE 10 and/or temperature data associated with the predicted location. In some embodiments, the UE 10 may be communicatively coupled to one or more sensors (e.g., a temperature sensor) associated with the predicted location. As such, the UE 10 may receive temperature data from the one or more sensors based on the indication of the predicated location.

As an example, the UE 10 may include a diving application. The user may set a target diving depth using the diving application of the UE 10. In some embodiments, the UE 10 may receive the target diving depth and determine the predicted location based on the target diving depth. Additionally or alternatively, the UE 10 may receive temperature data (e.g., water temperature data) associated with the target diving depth. The UE 10 determine an ambient temperature based on receiving temperature data. In particular, the UE 10 may determine the ambient temperature associated with the target diving depth based on receiving the indication of the predicted location. In some embodiments, the UE 10 may receive the ambient temperature (e.g., temperature data) from the diving application and/or via the Internet. In particular, the diving application and/or the Internet may include a plurality of ambient temperatures each corresponding to a respective temperature at a respective water depth.

As another example, the UE 10 may include a navigation application. The UE 10 may receive an indication of the predicted location based on received navigational data (e.g., received via the GNSS receiver 56). For example, the UE 10 may determine the predicted location based on a set navigational route. In particular, the predicted location may be a destination, a stop, or any other location associated with the navigational route. In addition, the UE 10 may receive temperature data based on the predicted location associated with the navigational route. For example, the UE 10 may receive temperature data from a weather application, the Internet, and the like, based on the predicted location. The UE 10 may receive and/or determine the ambient temperature of the predicted location associated with the UE 10 based on the temperature data.

As another example, the UE 10 may receive an indication of a predicted location based on a plurality of daily routing and/or commuting associated with the UE 10. For example, the UE 10 may track (e.g., continuously track) a location associated with the UE 10. Furthermore, the UE 10 may determine a daily routing and/or commuting associated with the UE 10 based on tracking the location of the UE 10 over time. Moreover, the UE may determine the predicted location based on the daily routing and/or commuting associated with the UE 10. For example, a user carrying the UE 10 may travel from home to and from work via a commuting route (e.g., a same commuting route) during each weekday, and the UE 10 may determine the predicted location based on the commuting route. The UE 10 may additionally receive temperature data based on the predicted location associated with the daily routing and/or commuting. As discussed herein, the UE 10 may receive temperature data from a weather application, the Internet, and the like, based on the predicted location. The UE 10 may receive and/or determine the ambient temperature of the predicted location associated with the UE 10 based on the temperature data.

At process block 210, the UE 10 may determine whether the ambient temperature associated with predicted location is less than a threshold ambient temperature. In particular, as discussed herein, performance of certain operations of the UE 10 may be temperature dependent. For example, efficient operation of the battery of the UE 10 (e.g., amount of available charge, discharge performance, capacity) may depend on a temperature of the battery. The temperature of the UE 10 may correspond to the temperature of the battery. In addition, the temperature of the UE 10 may correspond to an ambient temperature associated with an environment or location at which the UE 10 is located. Furthermore, in some embodiments, the UE 10 may determine a threshold ambient temperature based on an operation temperature (e.g., optimal operation temperature) associated with the UE 10. The threshold ambient temperature may correspond to a temperature threshold (e.g., lowest temperature threshold) at which the battery of the UE 10 may operate efficiently (e.g., may operate as normal, operate as expected, operate within threshold performance levels). As an example, the ambient temperature threshold may be 10° C. In additional or alternative embodiments, the ambient temperature threshold may be 10° C. or more, 10° C. or less, 5° C. or less, 0° C. or less, and so on. In some embodiments, the ambient temperature threshold may be set (e.g., programmed, input, determined) via user input and/or during manufacturing. In some embodiments, the ambient temperature threshold may be determined via machine learning and/or artificial intelligence techniques or processes.

If the UE 10 determines that the ambient temperature is not less than the threshold ambient temperature, the UE 10 may display the indication of the state of charge (process block 206). If the UE 10 determines that the ambient temperature is less than the threshold ambient temperature, at process block 212, the UE 10 may determine whether a temperature difference between a current temperature associated with the UE 10 and the ambient temperature is greater than a threshold temperature difference. In particular, the UE 10 may receive temperature data indicative of a current temperature (e.g., current ambient temperature) associated with the UE 10. In some embodiments, the UE 10 may receive the current temperature (e.g., temperature data) via sensor data received from one or more sensors (e.g., temperature sensor 58) associated with the UE 10. The one or more sensors may be configured to monitor or detect a temperature associated with a current environment surrounding the UE 10 (e.g., air temperature data), a temperature (e.g., internal temperature) of the UE 10, and/or a temperature associated with the battery of the UE 10. In some embodiments, the UE 10 may determine the current temperature associated with the UE 10 based on a location (e.g., current location) of the UE 10. In particular, the UE 10 may receive location information indicative of a location of the UE 10 (e.g., a current location). The UE 10 may receive location information (e.g., via the GNSS receiver 56) from a global navigation satellite system. In some embodiments, the UE 10 may receive an indication of the current location of the UE 10 based on sensor data. For example, the UE 10 may utilize image data (e.g., captured via a camera associated with the UE 10), Wi-Fi signals, cellular signals, sound data, and the like to determine a location of the UE 10. In some embodiments, for example, the UE 10 may determine that the UE 10 is located indoors based on receiving reflected Wi-Fi signals (e.g., reflected via walls of a structure). The UE 10 may receive temperature data from a weather application (e.g., weather forecast data, air temperature data), a diving application (e.g., temperature data associated with diving depths), the internet, and the like, based on the location of the UE 10. In addition, the UE 10 may determine a current ambient temperature associated with the UE 10 based on the temperature data. The current ambient temperature may correspond to the current temperature of the UE 10.

The UE 10 may compare the current temperature associated with the UE 10 to the ambient temperature associated with the predicted location to determine a temperature difference. Furthermore, the UE 10 may compare the temperature difference to the threshold temperature difference. The threshold temperature difference may be indicative of a difference in temperature associated with the UE 10 that may impact performance of certain operations of the UE 10, such as the battery. In some embodiments, the threshold temperature difference may be set (e.g., programmed, input, determined) via user input and/or during manufacturing. In some embodiments, the threshold temperature difference may be determined via machine learning and/or artificial intelligence techniques or processes.

It should be understood that in some embodiments, the UE 10 may not determine whether the temperature difference between the current temperature associated with the UE 10 and the ambient temperature is greater than the threshold temperature difference. As such, in some embodiments, the method would proceed to process block 214 if the UE 10 determined that the ambient temperature is less than the threshold ambient temperature.

Continuing with process block 212, if the UE 10 determines that the temperature difference between the current temperature associated with the UE 10 and the ambient temperature is not greater than a threshold temperature difference, the UE 10 may display the indication of the state of charge (process block 206). If the UE 10 determines that the temperature difference between the current temperature associated with the UE 10 and the ambient temperature is greater than a threshold temperature difference, at process block 214, the UE 10 may receive a predicted shutdown point associated with the ambient temperature. In particular, the UE 10 may determine (e.g., generate, calculate) the predicted shutdown point based on the ambient temperature associated with the predicted location of the UE 10. Additionally, the UE 10 may determine the predicted shutdown point based on the ambient temperature associated with the predicted location of the UE 10 and the current state of charge of the battery of the UE 10. The predicted shutdown point may include a ratio of potential remaining available charge of the battery (e.g., based on the ambient temperature of the predicted location of the UE 10) to a maximum or total potential charge of the battery represented as a percentage of the total amount of charge of the battery (e.g., 0%, 5%). In particular, the predicted shutdown may indicate an amount of potential remaining charge of the battery at which the battery would potentially not have sufficient amount of charge to continue normal operations of the UE 10 (e.g., at the predicted location).

The UE 10 may use algorithms, machine learning, and/or artificial intelligence techniques to determine the predicted shutdown point based on the ambient temperature associated with the predicted location and/or the current state of charge of the battery. In some embodiments, the UE 10 may be communicatively coupled to a database configured to store a plurality of predicted shutdown points. In particular, the plurality of predicted shutdown points may be stored via a look up table that is configured to associate the plurality of predicted shutdown points with corresponding respective ambient temperatures and/or current state of charges. The UE 10 may query the database based on the ambient temperature and/or the current state of charge of the battery, and receive the predicted shutdown point from the database.

At process block 216, the UE 10 may determine whether the predicted shutdown point is less than the state of charge (e.g., current state of charge) of the battery of the UE 10. The UE 10 may compare the amount of charge associated with or indicated by the predicted shutdown point to the amount of charge associated with or indicated by the current state of charge of the battery. If the UE 10 determines that the predicted shutdown point is not less than the state of charge then, at process block 218, the UE 10 may display the indication of the state of charge (e.g., via the GUI). The UE 10 may display the indication of the state of charge and the indication of the current shutdown point associated with the battery of the UE 10. In some embodiments, the UE 10 may additionally display an indication of the current state of charge of the battery being less than the predicted shutdown point (e.g., overlaying or in combination with the display of the indication of the state of charge). In particular, the indication of the current state of charge of the battery being less than the predicted shutdown point may notify the user that the current amount of charge associated with the battery may not be sufficient to power the UE 10 (e.g., operations of the UE 10) at the predicted location. As an example, the UE 10 may display the indication of the state of charge in a different color (e.g., different than a normal color used for display of the indication of the state of charge), and/or may include an additional visual feature (e.g., visual characteristic) such as a symbol, an icon, a marking, hash-lines, and the like to indicate that the current state of charge of the battery is less than the predicted shutdown point. In some embodiments, additionally or alternatively, the indication that the current state of charge of the battery is less than the predicted shutdown point may include audio output (e.g., via speakers associated with the UE 10), such as a tone, a chime, or a voice message.

In some embodiments, the UE 10 may present (e.g., send, display, via the GUI) a notification that alerts a user of the UE 10 that the current state of charge of the battery is less than the predicted shutdown point. In particular, the notification may notify the user of a potential (e.g., future) shutdown event. The notification of the potential shutdown event may indicate that the current amount of charge associated with the battery may not be sufficient to power the UE 10 (e.g., operations of the UE 10) at the predicted location. The notification may include visual elements, such as text, picture, symbols, icons, and like, that indicate that the current state of charge of the battery is less than the predicted shutdown point. Additionally or alternatively, the notification may include audio output (e.g., via speakers associated with the UE 10), such as a tone, a chime, or a voice message.

If the UE 10 determines that the predicted shutdown point is less than the state of charge then, at process block 220, the UE 10 may display the indication of the state of charge and the predicted shutdown point (e.g., via the GUI). In particular, the UE 10 may display the indication of the state of charge and the indication of the current shutdown point associated with the battery of the UE 10, along with an indication of the predicted shutdown point. The UE 10 may present the predicted shutdown point as a visual indication, such as a symbol, an icon, and/or text via the GUI. Additionally or alternatively, in some embodiments, the UE 10 may present the predicted shutdown point as an audio indication, via speakers associated with the UE 10. The indication of the predicted shutdown point may visually or audibly indicate a point at which the UE 10 may potentially initiate a sleep mode or a shutdown operation based on the current state of charge of the UE 10 and the ambient temperature associated with the predicted location of the UE 10. In addition, the indication of the predicted shutdown point may be displayed in relation to the indication of the state of charge and the indication of the current shutdown point. For example, the indication of the predicted shutdown point may visually indicate a point along the shape. In particular, the indication of the state of charge in relation to the predicted shutdown point may indicate an amount of available charge of the battery from the predicted shutdown point associated with the battery. In some embodiments, when the indication of the state of charge is visually equal to or within a threshold amount of the point along the shape (e.g., indication of the predicted shutdown point), the indication of the state of charge in relation to the predicted shutdown point may indicate that the UE 10 may potentially initiate the sleep mode or shutdown operation at the predicated location.

Continuing with the above example, an amount of potential charge associated with the predicted shutdown point may be represented as a third portion of the shape that is “filled” and/or that is distinguished from both the first portion of the shape that is associated with the current state of charge, and the second portion of the shape that is associated with an amount of the battery that does not include an available amount of charge (e.g., empty of charge). In addition, the predicted shutdown point may be represented as an “end” of the third portion, or as the battery discharges (e.g., an amount of remaining charge or the state of charge of the battery decreases), the first portion of the shape that is “filled” may decrease in size toward the “end”of the third portion.

In some embodiments, the UE 10 may present (e.g., send, display, via the GUI) a notification that alerts a user of the UE 10 that the predicted shutdown point is within a threshold amount of the current state of charge of the battery. In particular, the notification may notify the user of a potential (e.g., future) shutdown event. The notification of the potential shutdown event may indicate that the current amount of charge associated with the battery may not be sufficient to power the UE 10 (e.g., operations of the UE 10) at the predicted location and/or at a future time associated with the predicted location. The notification may include visual elements, such as text, picture, symbols, icons, and like, that indicate that the predicted shutdown point is within a threshold amount of the current state of charge of the battery. Additionally or alternatively, the notification may include audio output (e.g., via speakers associated with the UE 10), such as a tone, a chime, or a voice message.

It should be appreciated that, in some embodiments, if the UE 10 determines that the predicted shutdown point is not less than the state of charge or the state of charge is less than the predicted shutdown point then the UE 10 may display the indication of the state of charge and the predicted shutdown point (e.g., via the GUI). In some embodiments, the UE 10 may display the predicted shutdown point overlying or in combination with an indication of the indication of the state of charge. For example, the indication of the predicted shutdown point may be displayed as a marking (e.g., visually distinct marking), such as a line or symbol, that indicates the predicted shutdown point.

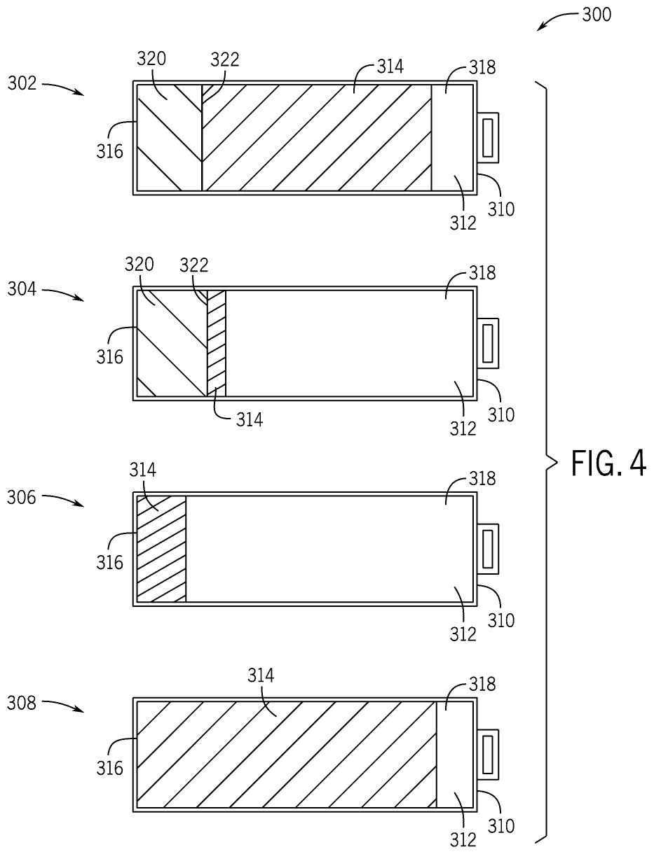

FIG. 4 is a schematic diagram of example indications 300 of a state of charge relative to a shutdown point configured to be displayed by the user equipment, according to embodiments of the present disclosure. In particular, the UE 10 may receive image data indicative of a respective image associated with display of the indication of the state of charge, the indication of the shutdown point, the indication of the predicted shutdown point, or any combination thereof. In addition, the UE 10 may be configured to display the image (e.g., image data) via a display (e.g., GUI). It should be understood that the example indications 300 are intended to illustrate exemplary images that are displayed, via the display of the UE 10, based on the image data associated with display of the indication of the state of charge, the indication of the shutdown point, the indication of the predicted shutdown point, or any combination thereof. In some embodiments, the UE 10 may be configured to receive additional image data and display additional images (e.g., not illustrated by FIG. 4) based on the additional image data associated with display of the indication of the state of charge, the indication of the shutdown point, the indication of the predicted shutdown point, or any combination thereof.

The example indications 300 may include a first example indication 302, a second example indication 304, a third example indication 306, and a fourth example indication 308. Each of the first, second, third, and fourth example indications 302, 304, 306, and 308 may include a respective outline 310 enclosing a respective interior space 312. The UE 10 may display the first example indication 302 based on a state of charge associated with the battery of the UE 10 being greater than the predictive shutdown point. In particular, the first example indication 302 may include a first portion 314 (e.g., within the outline 310, of the interior space 312) configured to indicate the current state of charge of the battery and a current shutdown point 316 configured to indicate a point at which the UE 10 may initiate a sleep mode or a shutdown operation based on a current ambient temperature (e.g., associated with a current location of the UE 10). The first example indication 302 may also include a second portion 318 (e.g., within the outline 310, of the interior space 312) configured to indicate an amount of the battery that does not include an available amount of charge (e.g., empty of charge). The second portion 318 may be visually distinct (e.g., include a different visual characteristic) from the first portion 314. For example, the second portion 318 may include a color or shade (e.g., white or no color) that is different from a color or shade (e.g., light gray) associated with the first portion 314. In addition, the first portion 314 may be adjacent the second portion 318. The first example indication 302 may also include a third portion 320 (e.g., within the outline 310, of the interior space 312) configured to indicate the predicted shutdown point (e.g., an amount of potential charge associated with the predicted shutdown point). The third portion 320 may include an end 322 configured to indicate a point at which the UE 10 may initiate a sleep mode or a shutdown operation based on the current state of charge being less than or equal to the predicted shutdown point (e.g., an amount of charge is not sufficient for normal operations of the UE 10). The third portion 320 may be visually distinct from the first portion 314 and the second portion 318. For example, the third portion 320 may include a color or shade (e.g., dark gray) that is different from a color or shade associated with the first portion 314 and a color or shade associated with the second portion 318. The third portion 320 may be adjacent the first portion 314, and the first portion 314 maybe between the second portion 318 and the third portion 320.

The UE 10 may display the second example indication 304 based on a state of charge being greater than the predictive shutdown point and less than a threshold difference amount (e.g., threshold difference value) from the predictive shutdown point. In particular, the second example indication 304 may include the first portion 314 configured to indicate the current state of charge of the battery and the current shutdown point 316 configured to indicate a point at which the UE 10 may initiate a sleep mode or a shutdown operation based on a current ambient temperature (e.g., associated with a current location of the UE 10). The first portion 314 may be visually distinct (e.g., include a different visual characteristic) from the first portion 314 as displayed in the first example indication 302. In particular, the first portion 314 associated with the second example indication 304 may include a different visual characteristic (e.g., different color or shading). For example, the first portion 314 of the second example indication 304 may include a color or shade (e.g., red) that is different from the first portion 314 of the first example indication 302. In some embodiments, the UE 10 may determine a difference value between the state of charge of the battery and the predicted shutdown point, and display the second example indication 304 based on the difference value being less than the threshold difference amount.

The second example indication 304 may also include the second portion 318 configured to indicate an amount of the battery that does not include an available amount of charge (e.g., empty of charge). The second portion 318 may be visually distinct (e.g., include a different visual characteristic) from the first portion 314. The second example indication 304 may also include the third portion 320 configured to indicate the predicted shutdown point (e.g., an amount of potential charge associated with the predicted shutdown point). The third portion 320 may include the end 322 configured to indicate a point at which the UE 10 may initiate a sleep mode or a shutdown operation based on the current state of charge being less than or equal to the predicted shutdown point (e.g., an amount of charge is not sufficient for normal operations of the UE 10). The third portion 320 may be visually distinct from the first portion 314 and the second portion 318. The first portion 314 associated with the second example indication 304 being visually distinct from the first portion 314 of the first example indication 302 and the second example indication 304 including the third portion 320 may indicate that the state of charge is greater than predictive shutdown point and less than the threshold difference amount from the predictive shutdown point.

The UE 10 may display the third example indication 306 based on a state of charge being less than the predictive shutdown point. In particular, the third example indication 306 may include the first portion 314 configured to indicate the current state of charge of the battery and the current shutdown point 316 configured to indicate a point at which the UE 10 may initiate a sleep mode or a shutdown operation based on a current ambient temperature (e.g., associated with a current location of the UE 10). The first portion 314 may be visually distinct from the first portion 314 as displayed in the first example indication 302. For example, the first portion 314 associated with the third example indication 306 may include a different color or shading (e.g., red) than a color or shade associated with the first portion 314 of the first example indication 302. The third example indication 306 may also include the second portion 318 configured to indicate an amount of the battery that does not include an available amount of charge (e.g., empty of charge). The second portion 318 may be visually distinct from the first portion 314. The first portion 314 associated with the third example indication 306 being visually distinct from the first portion 314 of the first example indication 302 and the third example indication 306 being absent of or not including a respective third portion (e.g., like the third portion 320 of the second example indication 304) may indicate that the state of charge is less than the predictive shutdown point.

The UE 10 may display the fourth example indication 308 based on the predictive shutdown operation being not enabled, the ambient temperature associated with the predicted location being greater than the threshold ambient temperature, and/or the temperature difference between the current temperature and the ambient temperature being less than the threshold temperature difference. In particular, the fourth example indication 308 may include the first portion 314 configured to indicate the current state of charge of the battery and the current shutdown point 316 configured to indicate a point at which the UE 10 may initiate a sleep mode or a shutdown operation based on a current ambient temperature (e.g., associated with a current location of the UE 10). The fourth example indication 308 may also include a second portion 318 configured to indicate an amount of the battery that does not include an available amount of charge (e.g., empty of charge). The second portion 318 may be visually distinct from the first portion 314. In this manner, the first, second, third, and fourth example indications 302, 304, 306, 308 may effectively communicate a state of charge associated with the battery of the UE 10. In particular, the first, second, and third example indications 302, 304, 306 may effectively communicate a predicted shutdown point associated with a predicted location of the UE 10 in relation to the current state of charge associated with the battery of the UE 10. Thus, a user associated with the UE 10 may have accurate information regarding a potential or future sleep mode or shutdown operation associated with the UE 10. The user may decide to recharge the UE 10 prior to traveling to another location, such as the predicted location, based on information communicated via the first, second, and third example indications 302, 304, 306. As such, the user may avoid the potential or future sleep mode or shutdown operation associated with the UE 10.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function]. . . ” or “step for [perform]ing [a function]. . . ,” it is intended that such elements are to be interpreted under 35 U.S.C. 112(f). However, for any claims containing elements designated in any other manner, it is intended that such elements are not to be interpreted under 35 U.S.C. 112(f).

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

1. One or more tangible, non-transitory, computer-readable media comprising instructions, that when executed by processing circuitry of a user equipment, cause the processing circuitry to:
receive a state of charge of a power source of the user equipment;
receive an ambient temperature of a location associated with the user equipment; and
provide an indication of a predicted shutdown point associated with the state of charge based on the ambient temperature being less than or equal to a threshold ambient temperature.

2. The one or more tangible, non-transitory, computer-readable media of claim 1, wherein the instructions, when executed by the processing circuitry, cause the processing circuitry to provide an additional indication of the state of charge based on the ambient temperature being greater than the threshold ambient temperature.

3. The one or more tangible, non-transitory, computer-readable media of claim 1, wherein the instructions, when executed by the processing circuitry, cause the processing circuitry to provide the indication of the predicted shutdown point associated with the state of charge based on the ambient temperature being less than or equal to the threshold ambient temperature and the state of charge being greater than the predicted shutdown point.

4. The one or more tangible, non-transitory, computer-readable media of claim 1, wherein the instructions, when executed by the processing circuitry, cause the processing circuitry to provide an additional indication of the state of charge based on the ambient temperature being less than or equal to the threshold ambient temperature and the state of charge being less than the predicted shutdown point.

5. The one or more tangible, non-transitory, computer-readable media of claim 1, wherein the instructions, when executed by the processing circuitry, cause the processing circuitry to cause a display of the user equipment to display the indication.

6. The one or more tangible, non-transitory, computer-readable media of claim 5, wherein the instructions, when executed by the processing circuitry, cause the processing circuitry to:
receive permission to display the predicted shutdown point; and
cause the display of the indication based on the permission.

7. The one or more tangible, non-transitory, computer-readable media of claim 1, wherein the instructions, when executed by the processing circuitry, cause the processing circuitry to receive, via a global navigation satellite system receiver of the user equipment, the location associated with the user equipment.

8. The one or more tangible, non-transitory, computer-readable media of claim 1, wherein the instructions, when executed by the processing circuitry, cause the processing circuitry to receive temperature data comprising the ambient temperature, and wherein the temperature data corresponds to weather forecast data associated with the location, water temperature data associated with the location, or air temperature data associated with the location.

9. The one or more tangible, non-transitory, computer-readable media of claim 1, wherein the instructions, when executed by the processing circuitry, cause the processing circuitry to:
determine whether the state of charge is less than the predicted shutdown point; and
cause a display of the user equipment to display a notification indicative of a future shutdown event based on the state of charge being less than the predicted shutdown point.

10. An electronic device comprising:
a receiver; and
processing circuitry coupled to the receiver, the processing circuitry configured to:
receive a state of charge of a power source of the electronic device;
receive an ambient temperature of a location associated with the electronic device;
determine a predicted shutdown point associated with the state of charge based on the ambient temperature; and
provide an indication of the predicted shutdown point based on the ambient temperature being less than a threshold ambient temperature.

11. The electronic device of claim 10, wherein the location is associated with a route, a calendar entry, a reservation, or a purchase received via the electronic device.

12. The electronic device of claim 10, wherein the processing circuitry is configured to provide an additional indication of the state of charge based on the ambient temperature being less than or equal to the threshold ambient temperature and the state of charge being less than the predicted shutdown point.

13. The electronic device of claim 10, wherein the processing circuitry is configured to provide an additional indication of the state of charge based on the ambient temperature being greater than the threshold ambient temperature, the electronic device comprising a display configured to display the indication or the additional indication.

14. The electronic device of claim 13, wherein the processing circuitry is configured to determine whether the state of charge is below the predicted shutdown point, and wherein the display is configured to display a notification indicative of a future shutdown event based on the state of charge being below the predicted shutdown point.

15. The electronic device of claim 10, wherein the indication comprises image data indicative of an image comprising a first portion of an interior space enclosed by an outline adjacent to a second portion of the interior space, wherein the first portion visually indicates the predicted shutdown point and the second portion visually indicates the state of charge.

16. The electronic device of claim 15, wherein the first portion comprises a different shade or color than the second portion.

17. A method performed by an electronic device comprising:
receiving, via processing circuitry of the electronic device, a state of charge of a power source of the electronic device;
receiving, via the processing circuitry, a first indication that a predictive shutdown operation associated with the electronic device is enabled;
receiving, at the processing circuitry, an ambient temperature of a location associated with the electronic device based on the predictive shutdown operation being enabled;
displaying, via a display of the electronic device, a second indication of a predicted shutdown point and the state of charge based on the ambient temperature being less than or equal to a threshold ambient temperature; and
displaying, via the display, a third indication of the state of charge based on the ambient temperature being greater than the threshold ambient temperature.

18. The method of claim 17, comprising displaying, via the display, a fourth indication of the state of charge based on the ambient temperature being less than or equal to the threshold ambient temperature and the state of charge being less than the predicted shutdown point, wherein the fourth indication of the state of charge comprises a first visual characteristic different than a second visual characteristic of the third indication of the state of charge.

19. The method of claim 17, comprising:
receiving, via the processing circuitry, a fourth indication that the predictive shutdown operation associated with the electronic device is not enabled; and
displaying, via the display, a fifth indication of the state of charge of the electronic device based on the fourth indication.

20. The method of claim 17, comprising:
receiving, via the processing circuitry, a difference value between the state of charge and the predicted shutdown point; and
displaying, via the display, a fourth indication of the predicted shutdown point and the state of charge based on the difference value being less than a threshold difference value, wherein a visual representation of the state of charge associated with the fourth indication comprises a first visual characteristic that is distinct from a second visual characteristic associated with an additional visual representation of the state of charge associated with the second indication.
